(19) United States
(12) Patent Application Publication
(10) Pub. No.: US 2024/0222435 A1
(43) Pub. Date: Jul. 4, 2024

(54) COUPLING A LAYER OF SILICON CARBIDE WITH AN ADJACENT LAYER

(71) Applicant: Intel Corporation, Santa Clara, CA (US)

(72) Inventors: Abhishek Anil SHARMA, Portland, OR (US); Han Wui THEN, Portland, OR (US); Wilfred GOMES, Portland, OR (US); Anand S. MURTHY, Portland, OR (US); Tahir GHANI, Portland, OR (US); Sagar SUTHRAM, Portland, OR (US); Pushkar RANADE, San Jose, CA (US)

(21) Appl. No.: 18/089,936

(22) Filed: Dec. 28, 2022

(51) Int. Cl. H01L 29/16; H01L 21/02; H01L 27/105

(52) U.S. Cl. CPC H01L 29/1608; H01L 21/02447; H01L 21/02529; H01L 27/105

(57) ABSTRACT

Embodiments described herein may be related to apparatuses, processes, systems, and/or techniques for fabricating semiconductor packages that use a SiC layer that is coupled with another layer that includes another material. The SiC layer may be an active layer that includes devices, such as transistors, that are coupled with devices that may be in the other layer. The SiC layer may be coupled with the other layer using fusion bonding, hybrid bonding, layer transfer, and/or bump and island formation techniques. Other embodiments may be described and/or claimed.

### FIELD

Embodiments of the present disclosure generally relate to the field of semiconductor manufacturing, and in particular to packages that include a silicon carbide layer coupled with an adjacent layer.

### BACKGROUND

Continued growth in virtual machines, cloud computing, and portable devices will continue to increase the demand for high density transistors within chips and packages. This is particularly true with compute dies that are interacting with large amounts of memory for high bandwidth (HBW) computing where increased amounts of power may be required for operation.

### BRIEF DESCRIPTION OF THE DRAWINGS

FIGS. 1A-1B show various cross-section side views of diagrams of a semiconductor package that include a silicon carbide (SiC) layer, a gallium nitride (GaN) layer, and a silicon (Si) layer proximate to each other, in accordance with various embodiments.

FIG. 2 shows example structures of a layer that includes SiC that is coupled with another layer that includes another material, in accordance with various embodiments.

FIGS. 3A-3C illustrate stages in a manufacturing process for fusion bonding a SiC layer with another layer, in accordance with various embodiments.

FIGS. 4A-4C illustrate cross-section side views of stages in a manufacturing process for hybrid bonding a SiC layer with another layer, in accordance with various embodiments.

FIGS. 5A-5D illustrate cross-section side views of stages in a manufacturing process for layer transferring a SiC layer onto another layer, in accordance with various embodiments.

FIGS. 6A-6B show a top-down view and a cross-section side view of a SiC layer coupled with other layers using bumps and island formation, in accordance with various embodiments.

FIGS. 7A-7G show example configurations of SiC layers coupled with other layers, in accordance with various embodiments.

FIG. 8 illustrates a side view of a diagram of a wafer scale engine (WSE) that includes Zetta memory that is powered by high voltage input that is converted using devices within a SiC layer coupled with devices within a GaN layer, in accordance with various embodiments.

FIG. 9 illustrates an example process for creating a package that includes a SiC layer that is coupled with another layer that includes another material, in accordance with various embodiments.

FIG. 10 illustrates a computing device in accordance with one implementation of the invention.

FIG. 11 illustrates an interposer that includes one or more embodiments of the invention.

FIG. 12A illustrates a computing device in accordance with one implementation of an embodiment of the present disclosure.

FIG. 12B illustrates a processing device in accordance with one implementation of an embodiment of the present disclosure.

### DETAILED DESCRIPTION

Embodiments described herein may be related to apparatuses, processes, systems, and/or techniques for fabricating semiconductor packages, or integrated circuit structures, that use a SiC layer that is coupled with another layer that may include, for example but not limited to, silicon (Si), germanium (Ge), nitrogen (N), gallium (Ga), arsenic (As), silicon germanium (SiGe), gallium nitride (GaN), SiC, or gallium arsenide (GaAs). In embodiments, the SiC layer may be an active layer that includes devices, such as transistors, that are coupled with devices that may be in the other layer. In embodiments, a SiC layer may be coupled with the other layer using fusion bonding, hybrid bonding, layer transfer, and/or bump and island formation techniques.

In some embodiments, a SiC layer may be coupled with a GaN layer, where transistors in the SiC layer are electrically coupled with transistors in the GaN layer. These embodiments may be used to step down high-voltages, e.g. greater than 1 kV, provided to the package to 1-1.8 V for use by electrical components within the package. By providing high voltages to the package, greater electrical power is provided to operate a very large number of components, such as processor chips or memory within or coupled with package.

In embodiments, the devices in the SiC layer may be used to initially step down a higher voltage, e.g. greater than 1 kV, on one side of the SiC layer to a medium voltage, e.g. 200 V, on the other side of the SiC layer that is next to a GaN layer. Devices in the GaN layer may be used to further step down the medium voltage of 200 V to a lower voltage, for example 1-1.8 V, which may then be used by chips and other devices within the package. In embodiments, by using devices within the SiC and GaN layers to step down voltages from an initial high-voltage, a far greater amount of power may be provided to the package as opposed to legacy packages that only receive voltages between 1-1.8 V. In embodiments, a high voltage source may be provided through bumps at a side of the package.

In embodiments, a silicon layer may be coupled with the GaN layer, where the silicon layer includes transistors or other devices that may be used to provide signal processing. In some embodiments, the SiC layer may be directly coupled with the silicon layer.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

In embodiments, high-Tc conductors are utilized for global routing. Implementation of embodiments described herein can include the presence of such materials in a metal layer and/or at the package level. Implementation of embodiments described herein can include the fabrication of inductors and/or through silicon vias (TSVs) with the same. Implementation of embodiments described herein can include fabrication of a separate metal stack (bonded or monolithic) for custom routing of finished product wafers. Implementation of embodiments described herein can include the introduction of high Tc superconductors (single crystal or deposited—atomic layer deposition (ALD) and/or chemical vapor deposition (CVD) may be used to reduce the IR drop across long distances including between die stitching.

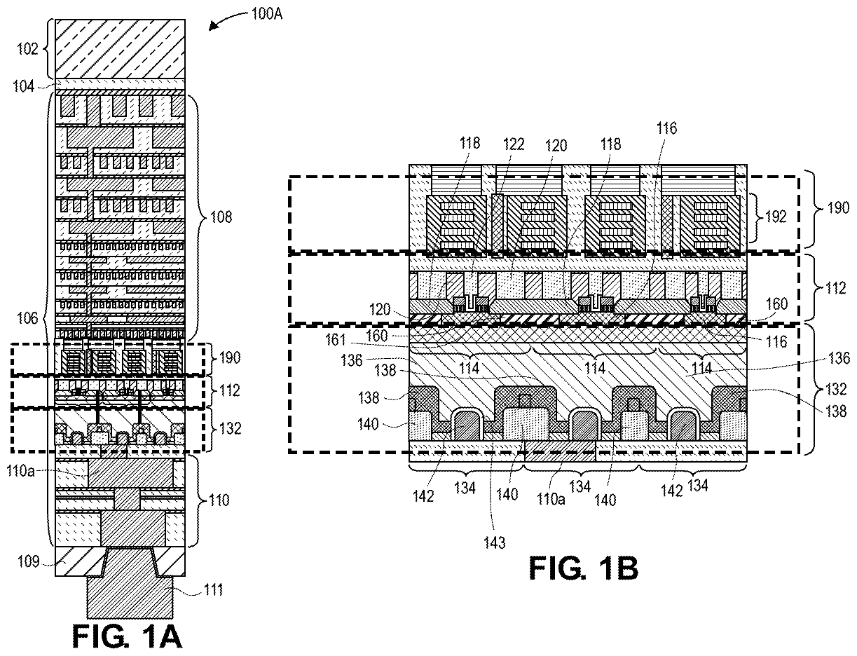

FIGS. 1A-1B show various cross-section side views of diagrams of a semiconductor package that include a silicon carbide (SiC) layer, a GaN layer, and a silicon (Si) layer proximate to each other, in accordance with various embodiments.

In FIG. 1A, diagram 100A shows an embodiment that is a side view that shows a carrier wafer 102 that is bonded to a package 106 using an adhesive 104. The package 106 may include front side routing layers 108, which may include traces and conductive vias used to route low-voltage power and/or signals, e.g. 1-1.8 V. The package 106 may also include back side routing layers 110, which may include power routings and conductive vias, that may route high-voltage power, e.g. handle voltage sources that are greater than 1 kV.

In embodiments, a Si layer 190 may be electrically coupled with and below the front side routing layers 108, and may include various devices (described in FIG. 1B). The GaN layer 112 may be below the Si layer 190 and various devices (described in FIG. 1B) within the GaN layer 112 may be electrically coupled with the Si layer 190. A SiC layer 132 may be between the GaN layer 112 and the back side routing layers 110, and various devices (described in FIG. 1B) formed within the SiC layer 132 may be electrically coupled with one or more of the routing elements within the back side routing layers 110, for example high-voltage connector 110a. In embodiments, a bump 111, which may include a solder ball or a copper pad, may be electrically coupled with the back side routing layers 110 to provide high-voltage power from an outside source. In embodiments, the bump 111 may be surrounded by a dielectric 109.

FIG. 1B illustrates an enlarged view of the Si layer 190, the GaN layer 112 and the SiC layer 132 of diagram 100A of FIG. 1A. In embodiments, the Si layer 190 may include a plurality of devices 192 that include silicon. Examples of the devices 192 include CMOS devices, interconnects, passive devices such as capacitors and diodes, and/or digital and analog circuitries made from CMOS devices. In embodiments, the GaN layer 112 may include a plurality of transistors 114 that are on a GaN material 116. Each of the transistors 114 may include a doped GaN region 118, which may have an N+ doping, onto which contacts 120 are coupled. A gate 122 may be between the various contacts 120. In embodiments, there may be one or more vias (not shown) between a contact 120 and the front side routing layers 108 of FIG. 1A to provide a lower voltage, for example between 1 and 1.8 V, to the front side routing layers 108. Note that in this embodiment, the transistors 114 are “face up,” with the contacts 120 and the gate 122 facing toward the front side routing layers 108 of FIG. 1A. In other embodiments, the transistors 114 may be in some other configuration or some other orientation. In embodiments, one or more back side power connectors 160, which may be Power Vias™, may electrically couple with the doped GaN region 118. In addition, there may be additional elements, such as interconnects, thru silicon vias and capacitors (not shown) within the GaN layer 112.

In embodiments, the SiC layer 132 may include a plurality of transistors 134 that are within a SiC material 136. The transistors 134 may include a doped region 138 onto which contacts 140 are coupled. A gate 142 may be formed between the contacts 140. In embodiments, the gate 142 may be a poly silicon gate that may be surrounded by another suitably doped semiconductor region 143. In embodiments, the gate 142 and/or the contacts 140 may be electrically coupled with the high-voltage connector 110a, that may be coupled with the back side routing layers 110 of FIG. 1A. Note that in this embodiment, the transistors 134 are “face down,” with contacts 140 and the gate 142 facing toward the back side routing layers 110 of FIG. 1A. In embodiments, this configuration may allow a more efficient, lower loss connection with the high-voltage connector 110a. In other embodiments, the transistors 134 may be in some other configuration or some other orientation. In addition, there may be additional elements, such as interconnects, thru silicon vias and capacitors (not shown) within the SiC layer 132. In embodiments, there may be a doped SiC region 161, which may have a N+ doping, within the SiC layer 132.

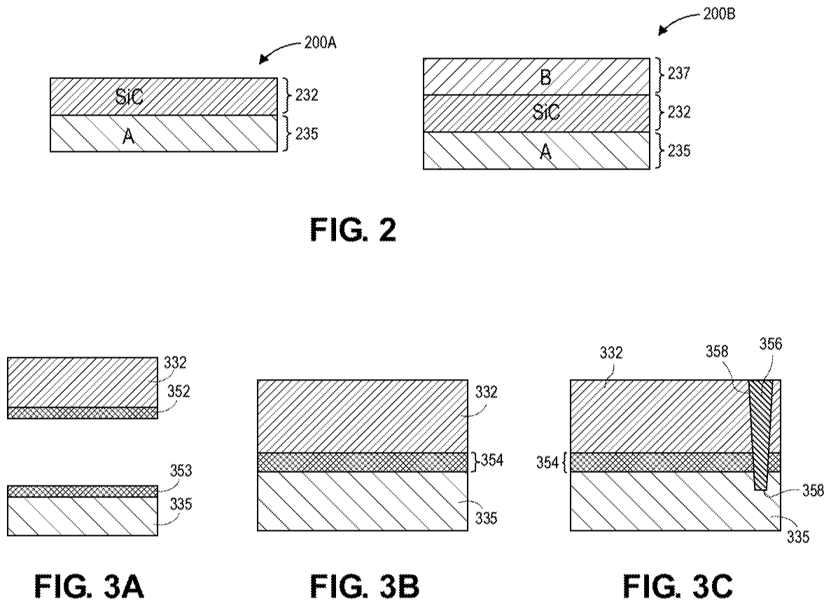

FIG. 2 shows example structures of a layer that includes SiC that is next to another layer that includes another material, in accordance with various embodiments. Partial package 200A shows a cross-section side view of a SiC layer 232, which may be similar to SiC layer 132 of FIG. 1B, that may be coupled with A layer 235. In embodiments, the A layer 235 may include material A which could be any material, and in embodiments may be a base wafer. Partial package 200B shows a cross-section side view of the SiC layer 232 that is coupled with A layer 235 that includes material A at a first side of the SiC layer 232, and is coupled with B layer 237 that includes material B on a second side of the SiC layer 232 opposite the first side. In embodiments, material A included within A layer 235 and material B included within layer B 237 may include, but are not limited to, Si, Ge, N, Ga, As, SiGe, GaN, SiC, or GaAs.

In embodiments, the techniques described below that may be used to couple the SiC layer 232 with the A layer 235. The techniques that may be used to couple the SiC layer 232 with the B layer 237 may be the same technique or may be different techniques. In embodiments, these techniques may include fusion bonding, hybrid bonding, layer transfer, or bump and island formation techniques. In other embodiments, SiC layer 232 may be grown on A layer 235, or layer B 237 may be grown on the SiC layer 232. In embodiments, one or more devices (not shown) may be included within the SiC layer 232, the A layer 235 and/or the B layer 237.

FIGS. 3A-3C illustrate stages in a manufacturing process for fusion bonding a SiC layer with another layer, in accordance with various embodiments. FIG. 3A shows a cross-section side view of a stage in the manufacturing process where a SiC layer 332, which may be similar to SiC layer 132 of FIGS. 1A-1B or SiC layer 232 of FIG. 2 is provided. In embodiments, the SiC layer 332 may be of arbitrary thickness, and may include one or more devices (not shown), such as transistors. In embodiments, the SiC layer 332 may be a wafer or a portion of a wafer that may be previously processed, for example patterned or unpatterned.

In embodiments, a bonding layer 352 may be coupled with a side of the SiC layer 332. In embodiments, the bonding layer 352 may be referred to as a fusion bonding layer. In embodiments, the bonding layer 352 may include Si, oxygen (O), carbon (C), and/or nitrogen (N). In embodiments, the bonding layer 352 may include SiN, SiON, SiCN, or SiOCN. The bonding layer 352 may be applied using deposition techniques such as chemical vapor deposition (CVD) or sputter deposition or high temperature growth in furnace.

In embodiments, a A layer 335 that includes material A, which may be similar to A layer 235 of FIG. 2, or GaN layer 112 of FIGS. 1A-1B, is provided. In embodiments, A layer 335 may include Si, Ge, N, Ga, As, SiGe, GaN, SiC, or GaAs. In embodiments, other materials may be used within A layer 335.

In embodiments, a bonding layer 353, which may be similar to bonding layer 352, may be coupled with a side of the A layer 335. In embodiments, the bonding layer 353 may be referred to as a fusion bonding layer. In embodiments, the bonding layer 353 may be applied using the techniques as described above for the bonding layer 352. Note that in some embodiments, both bonding layer 352 and bonding layer 353 may be used, only bonding layer 352, or only bonding layer 353 may be used.

FIG. 3B illustrates a cross-section side view of a stage in the manufacturing process where the SiC layer 332 is fusion bonded with the A layer 335. As a result of the fusion bonding, a bonding layer 354, which may include portions of bonding layer 352 and/or bonding layer 353 of FIG. 3A, may be formed between the SiC layer 332 and the A layer 335. In embodiments, fusion bonding may include bringing the bonding layer 352 and the bonding layer 353 of FIG. 3A together, and then applying an annealing process to apply heat. In embodiments, the annealing process may involve temperatures exceeding 700° to bond oxide interfaces.

FIG. 3C illustrates a cross-section side view of a stage in the manufacturing process where a via 356 may be formed through the SiC layer 332, through the bonding layer 354, and at least partially into A layer 335. In embodiments, the via 356 may be formed using a lithographic masking step followed by an etching process, and metal fill process. In embodiments, a barrier layer 358 may be formed that creates a separation barrier between the copper in the via 356 and the SiC layer 332, the A layer 335, and the bonding layer 354. In embodiments, the barrier layer 358 may be referred to as a diffusion barrier. In embodiments, these techniques may be used to couple, or bond, the SiC layer 332 to any material.

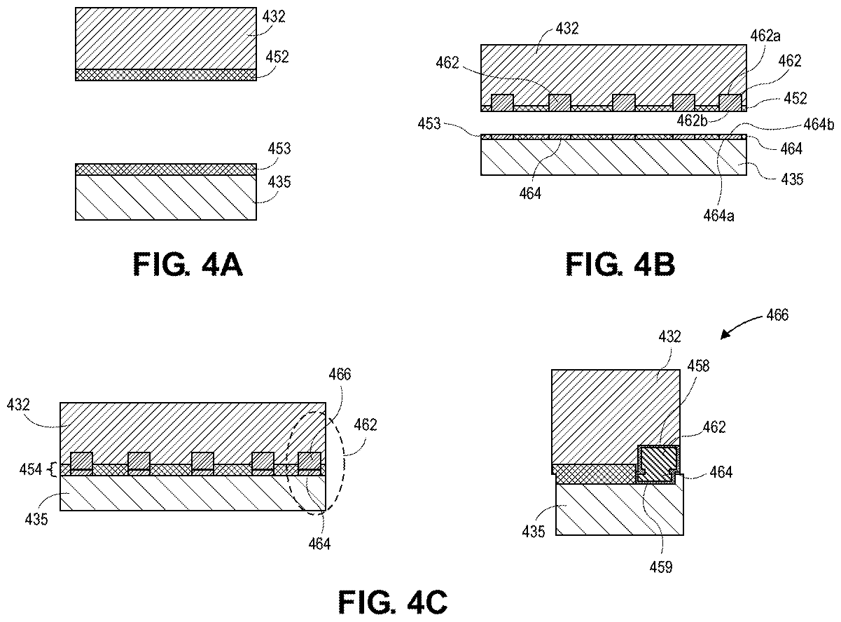

FIGS. 4A-4C illustrate cross-section side views of stages in a manufacturing process for hybrid bonding a SiC layer with another layer, in accordance with various embodiments. FIG. 4A, which may be similar to FIG. 3A, shows a cross-section side view of a stage in the manufacturing process where a SiC layer 432, which may be similar to SiC layer 132 of FIGS. 1A-1B or SiC layer 232 of FIG. 2, is provided. In embodiments, the SiC layer 432 may be of arbitrary thickness, and may include one or more devices (not shown), such as transistors. In embodiments, the SiC layer 432 may be a wafer or a portion of a wafer that may be previously processed, for example patterned or unpatterned.

In embodiments, a bonding layer 452 may be coupled with a side of the SiC layer 432. In embodiments, the bonding layer 452 may be referred to as a fusion bonding layer. In embodiments, the bonding layer 452 may include Si, O, C, and/or N. In embodiments, the bonding layer 452 may include SiN, SiON, SiCN, or SiOCN. The bonding layer 452 may be applied using techniques described above for bonding layer 352 of FIG. 3A.

In embodiments, a A layer 435 that includes material A, which may be similar to A layer 235 of FIG. 2 or GaN layer 112 of FIGS. 1A-1B, is provided. In embodiments, A layer 435 may include Si, Ge, N, Ga, As, SiGe, GaN, SiC, or GaAs. In embodiments, other materials may be used within A layer 435.

In embodiments, a bonding layer 453, which may be similar to bonding layer 452, may be coupled with a side of the A layer 435. In embodiments, the bonding layer 453 may be referred to as a fusion bonding layer. In embodiments, the bonding layer 453 may be applied using the techniques as described above for the bonding layer 452. Note that in some embodiments, both bonding layer 452 and bonding layer 453 may be used, only bonding layer 452, or only bonding layer 453 may be used.

FIG. 4B shows a cross-section side view of a stage in the manufacturing process where copper features 462 may be formed into the SiC layer 432 and appear at a side of the SiC layer 432 proximate to the bonding layer 452. Similarly, copper features 464 may be formed into the A layer 435 and appear at a side of the A layer 435 proximate to the bonding layer 453.

In embodiments, the copper features 462, 464 may be vias or pads. In embodiments, the copper features 462, 464 may be coupled with devices (not shown) respectively, within the SiC layer 432 or the A layer 435. In embodiments, at least some of the copper features 462 and at least some of the copper features 464 will be opposite to each other (as shown). In embodiments where the copper features 462 are vias, a top 462a may be narrower than a bottom 462b, and in embodiments where the copper features 464 are vias, a top 464a may be narrower than a bottom 464b.

In some embodiments, the copper features 462 may be formed into the SiC layer 432 prior to application of the bonding layer 452. In these embodiments (not shown), the bonding layer 452 may cover a surface of the copper features 462, and a planarization process may then be used to expose the bottom 462b of the copper features 462. Similarly, copper features 464 may be formed into the A layer 435 prior to application of the bonding layer 453. In these embodiments (not shown), the bonding layer 453 may cover a surface of the copper features 464, and a planarization process may then be used to expose the bottom 464b of the copper features 464. In other embodiments, the copper features 462 may be formed after the bonding layer 452 is applied to the SiC layer 432, and the copper features 464 may be formed after the bonding layer 453 is applied to the A layer 435.

FIG. 4C shows a cross-section side view of a stage in the manufacturing process where a hybrid bonding process occurs to couple SiC layer 432 with the A layer 435. In embodiments, the hybrid bonding process, which may be similar to the annealing and/or fusion process described above with respect to FIG. 3C, bonds the SiC layer 432 to A layer 435 with the bonding layer 454 separating them. In embodiments, the bonding layer 454 may result from the bonding layer 452 and/or the bonding layer 453 from FIG. 4B after annealing. As a result, copper features 462 and copper features 464 may be direct bonded to each other where copper meets copper, establishing a metal-to-metal connection with ultra-low resistivity.

Diagram 466 shows a detail of a direct bonding between a copper feature 462 within the SiC layer 432 and a copper feature 464 within the A layer 435, in accordance with an embodiment. A barrier layer 458 may at least partially surround the copper feature 462, and another barrier layer 459 may at least partially surround the copper feature 464. In embodiments, the barrier layers 458, 459 may be similar to barrier layer 358 of FIG. 3C, and may serve as a copper diffusion barrier. In embodiments, the copper feature 462 and the copper feature 464 may be misaligned as shown. In other words, a surface of the copper feature 462 may at least partially overlap with a surface of the copper feature 464.

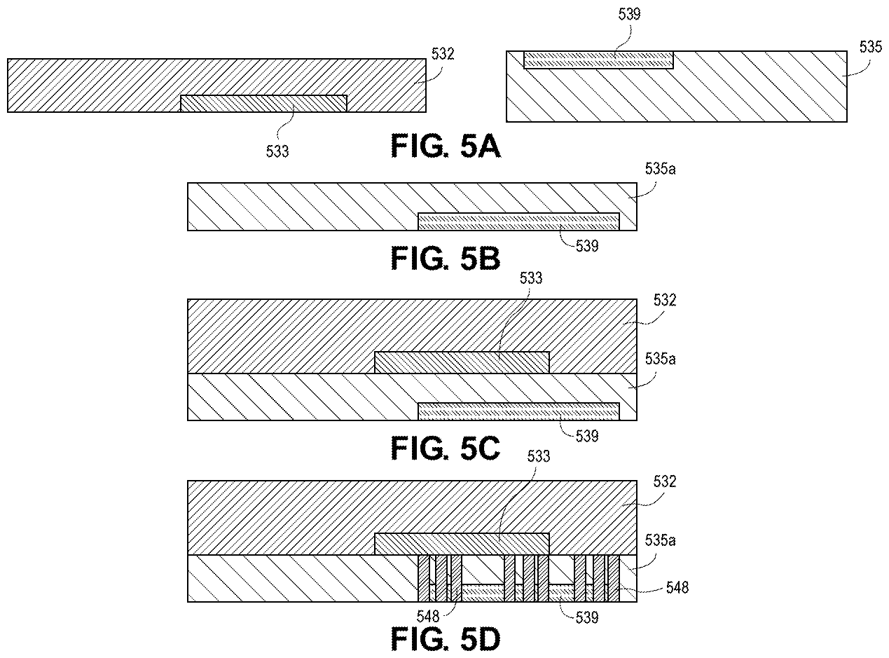

FIGS. 5A-5D illustrate cross-section side views of stages in a manufacturing process for layer transferring a SiC layer onto another layer, in accordance with various embodiments. FIG. 5A shows a cross-section side view of a stage in the manufacturing process where a SiC layer 532, which may be similar to SiC layer 132 of FIGS. 1A-1B or SiC layer 232 of FIG. 2, is provided. In embodiments, the SiC layer 532 may be of suitable thickness, e.g. ranging from ˜100 nm to several microns thick (considerations include allowing for the thickness of the device layer 533, ease of heat removal from device layer 533 and mechanical constraints e.g. die planarity), and may include one or more devices 533, which may include transistors. In embodiments, the SiC layer 532 may be a wafer or a portion of a wafer that may be previously processed, for example patterned or unpatterned.

In embodiments, a A layer 535 that includes material A, which may be similar to A layer 235 of FIG. 2, or GaN layer 112 of FIGS. 1A-1B, is provided. In embodiments, A layer 535 may include Si, Ge, N, Ga, As, SiGe, GaN, SiC, or GaAs. In embodiments, other materials may be used within A layer 535. In embodiments, A layer 535 may be of arbitrary thickness, and may include one or more devices 539, such as transistors. In embodiments, the A layer 535 may be a wafer or a portion of a wafer that may be previously processed, for example it may be patterned or unpatterned.

FIG. 5B shows a cross-section side view of a stage in the manufacturing process where the A layer 535 of FIG. 5A has been thinned down to form thinned A layer 35a. In embodiments, a thickness of the thinned A layer 535a may be 100 nm or less. Note that the devices 539 may not be affected by the thinning process.

FIG. 5C shows a cross-section side view of a stage in the manufacturing process where the A layer 535a is transferred onto the SiC layer 532. In embodiments, this is performed by applying high-pressure and/or temperature to compress and bond the A layer 535a onto the SiC layer 532. In embodiments, the A layer 535a may have been thick, for example several hundreds of micrometers, when bonded to the SiC layer 532, and subsequently thinned to a thickness of 100 nm or less. In embodiments, the thinning may be achieved by etching of the A layer 535a, or by cleaving. Cleaving is achieved by forming a cleave plane within the crystal structure of A layer 535a, for example by implantation of a foreign species such as hydrogen, into A layer 535a.

It should be appreciated that the location of the devices 533 within the SiC layer 532 may be anywhere within the SiC layer 532, and that the location of the devices 539 within the thinned A layer 535a, may be anywhere within the thinned A layer 535a. In some embodiments, the devices 533 may be directly electrically coupled with the devices 539 as a result of the layer transfer process.

FIG. 5D shows a cross-section side view of a stage in the manufacturing process where connections 548 may be formed through the thinned A layer 535a that may electrically couple devices 533 and devices 539. In embodiments, the connections 548 may extend completely through the thinned A layer 535a, or may be formed to couple other structures (not shown) within the thinned A layer 535a and the SiC layer 532.

In embodiments, the connections 548 may be formed using a lithography process that is applied on the thinned A layer 535a, and the connections 548 subsequently filled with copper. As a result, a pitch between the connections 548 may be made that is substantially smaller than pitches of connections (not shown) using drilling techniques. In embodiments, a pitch between the connections 548 may be 250 nm or less. Note that in some embodiments, the SiC layer 532 may be thinned, and then a layer transfer process applied to etch the thinned SiC layer 532 onto the A layer 535 of FIG. 5A. In these embodiments, lithography processes may be then be applied to the thinned SiC layer 532 to form connections similar to connections 548.

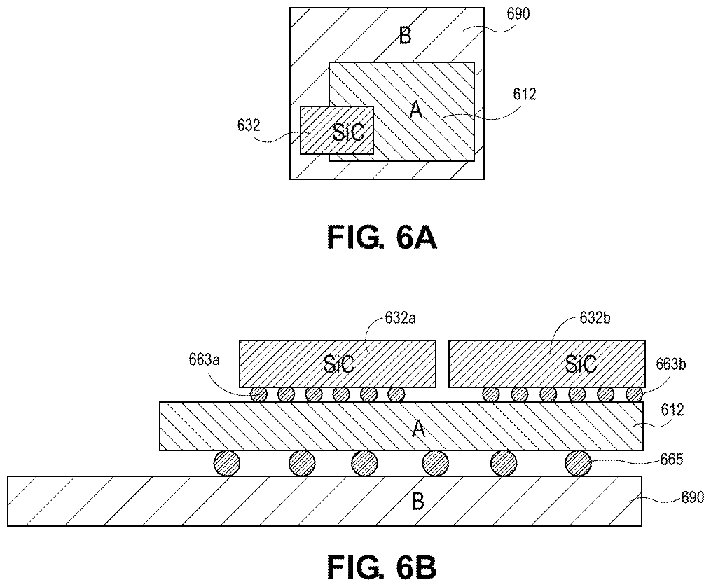

FIGS. 6A-6B show a top-down view and a cross-section side view of a SiC layer coupled with other layers using bumps and island formation, in accordance with various embodiments. FIG. 6A shows a top-down view that includes a B layer 690, which may be similar to Si layer 190 of FIGS. 1A-1B. In embodiments, a A layer 612, which may be similar to GaN layer 112 of FIGS. 1A-1B, may be on the B layer 690. A SiC layer 632 may be on the B layer 690. In embodiments, A layer 612 or B layer 690 may be wafers or portions of wafers, that may be patterned or unpatterned. In embodiments, A layer 612 or B layer 690 may include Si, Ge, N, Ga, As, SiGe, GaN, SiC, or GaAs. In embodiments, other materials may be used within A layer 612 or B layer 690.

FIG. 6B shows a side view of an implementation similar to FIG. 6A. B layer 690 may be a base layer, and may be of any thickness. B layer 690 may be physically and/or electrically coupled with A layer 612 using a ball grid array (BGA) 665. In other embodiments, the BGA 665 may include micro bumps, or may include some other electrical and/or physical coupling mechanism. In embodiments, a plurality of SiC layers 632a, 632b, may be coupled with the A layer 612 using BGA 663a, 663b respectively. In embodiments, the BGA 663a, 663b may include micro bumps, or may include some other electrical and/or physical coupling mechanism.

In some embodiments, all or part of A layer 612, B layer 690 and the SiC layers 632a, 632b may be coupled with other techniques described herein, including but not limited to fusion bonding as described with respect to FIGS. 3A-3C, hybrid bonding as described with respect to FIGS. 4A-4C, or layer transfer as described with respect to FIGS. 5A-5D.

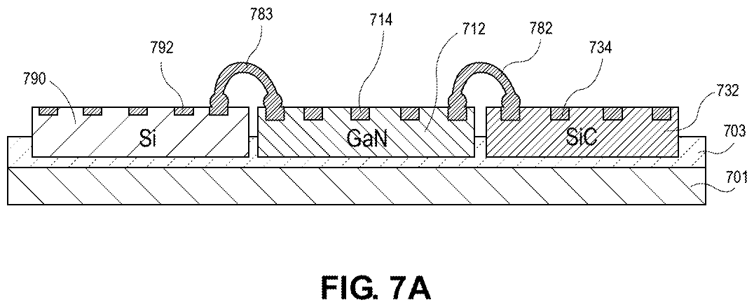

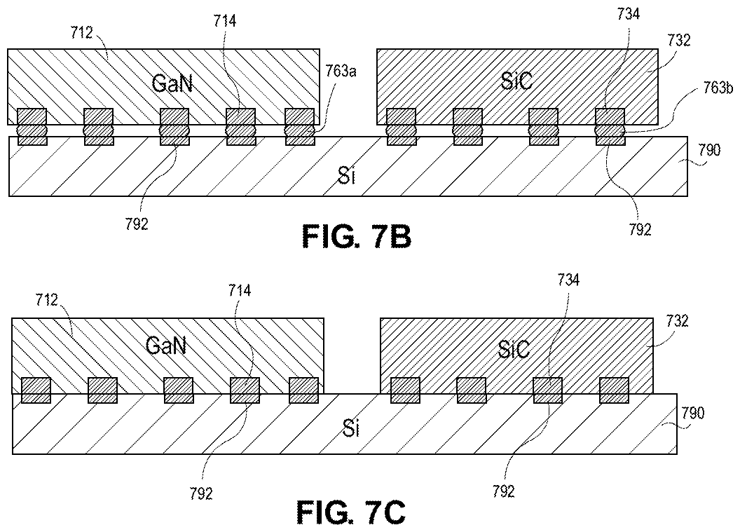

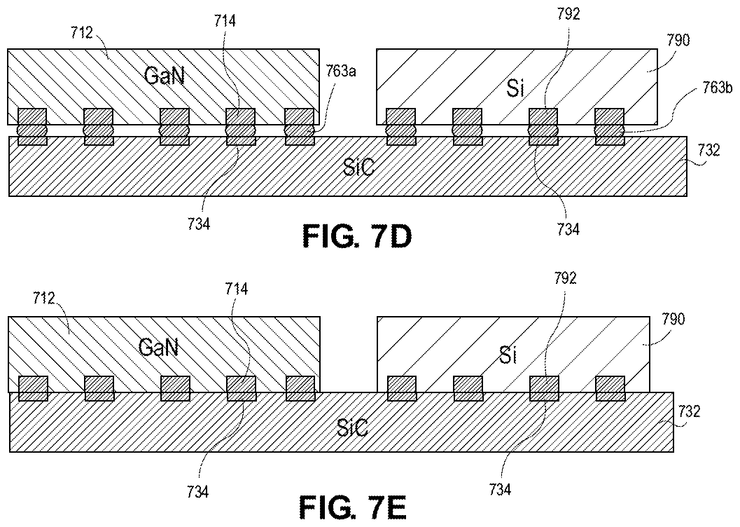

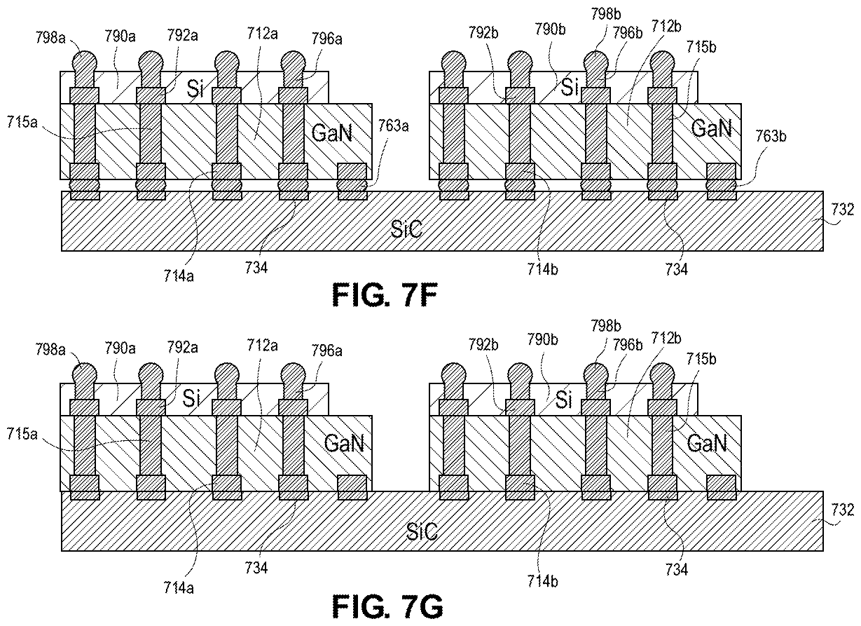

FIGS. 7A-7G show example configurations packages that include SiC layers coupled with other layers, for example those discussed with respect to FIGS. 6A-6B, in accordance with various embodiments. The examples shown in FIGS. 7B-7G are meant to be illustrative of embodiments, but are not an exhaustive list. FIG. 7A shows a cross-section side view of an example of a legacy implementation of a SiC layer 732 that include devices 734, represented as pads, which may be similar to SiC layer 132 and transistors 134 of FIGS. 1A-1B. A GaN layer 712 is shown that include devices 714, represented as pads, which may be similar to GaN layer 112 and transistors 114 of FIGS. 1A-1B. A Si layer 790 is shown that may include devices 792, represented as pads, which may be similar to Si layer 190 and devices 192 of FIGS. 1A-1B.

The SiC layer 732, GaN layer 712, and Si layer 790 may be coupled with a substrate 701 using an underfill material 703. In implementations, devices 734 may be electrically coupled with devices 714 using wire bonding 782, and devices 714 may be electrically coupled with devices 792 using wire bonding 783. In this legacy implementation, the various devices 734, 714, 792 are further away from each other than as shown in embodiments described herein. Wire bonds are resistive (they are longer and connect over farther distances between die), and presents high parasitic inductances which leads to higher losses and signal integrity issues.

FIG. 7B shows a cross-section side view of an embodiment that includes a Si layer 790 that includes devices 792. In embodiments, a GaN layer 712 that include devices 714 may be physically and electrically coupled with the Si layer 790 using BGA 763a. A SiC layer 732 that includes devices 734 may be electrically and physically coupled with the Si layer 790 using BGA 763b. In embodiments, the BGA 763a, 763b may be micro bumps.

FIG. 7C shows a cross-section side view of the embodiment shown in FIG. 7B, but with the GaN layer 712 and the SiC layer 732 directly coupled with the Si layer 790 using hybrid bonding techniques that may be similar to those discussed above with respect to FIGS. 4A-4C. In this way, the devices 714 and the devices 734, represented as copper pads, are direct bonded to devices 792. This implementation may reduce the IR loss that a BGA, such as BGA 763a, 763b of FIG. 7B, would otherwise introduce.

FIG. 7D shows a cross-section side view of an embodiment that includes a SiC layer 732, which may be a base wafer, that includes devices 734. A GaN layer 712 that includes devices 714 may be electrically and physically coupled with the SiC layer 732 using BGA 763a. A Si layer 790, which may include devices 792, may be electrically and physically coupled with the SiC layer 732 using BGA 763b. In these embodiments, the SiC layer 732 may be coupled with a high voltage source, for example a voltage greater than 1 kV, with the devices 734 stepping down the received voltage to a lower voltage, for example 200 V, which may then be coupled with the GaN layer 712 for the devices 714 to further step down the voltage to a 1-1.8V range.

FIG. 7E shows a cross-section side view of the embodiment shown in FIG. 7D, except that the GaN layer 712 and the Si layer 790 are directly coupled with the SiC layer 732 using hybrid bonding techniques that may be similar to those discussed above with respect to FIGS. 4A-4C. In this way, the devices 714 and the devices 792, represented as copper pads, are direct bonded to the devices 734. This implementation may reduce the IR loss that a BGA, such as BGA 763a, 763b of FIG. 7D would otherwise introduce.

FIG. 7F shows a cross-section side view of an embodiment that includes a SiC layer 732, which may be a base wafer, that includes devices 734 and a first GaN layer 712a, which may include devices 714a, that may electrically and physically couple with the devices 734 using a first BGA 763a. A second GaN layer 712b, which may include devices 714b, may electrically and physically couple with the devices 734 using a second BGA 763b.

In embodiments, a first Si layer 790a with devices 792a may directly electrically couple with GaN vias 715a, that may be filled with copper or with some other conductive material, that extend through the first GaN layer 712a. In embodiments, the first Si layer 790a may be hybrid bonded with the first GaN layer 712a, where the devices 792a may be direct bonded to the GaN vias 715a. In embodiments, a Si via 796a may electrically couple with a device 792a, and couple with a corresponding connector 798a on a side of the first Si layer 790a. In embodiments, the corresponding connector 798a may be a solder ball.

In embodiments, a second Si layer 790b with devices 792b may directly electrically couple with GaN vias 715b, that may be filled with copper, that extend through the second GaN layer 712b. In embodiments, the second Si layer 790b may be hybrid bonded with the second GaN layer 712b, where the devices 792b may be direct bonded to the GaN vias 715b. In embodiments, a Si via 796b may electrically couple with devices 792b, and couple with a corresponding connector 798b on a side of the second Si layer 790b. In embodiments, the corresponding connector 798b may be a solder ball.

FIG. 7G shows a cross-section side view of the embodiment shown in FIG. 7F, except that the first GaN layer 712a and the second GaN layer 712b are directly coupled with the SiC layer 732 using hybrid bonding techniques that may be similar to those discussed above with respect to FIGS. 4A-4C. In this way, the devices 714a, 714b, represented as copper pads, are direct bonded to the devices 734. This implementation may reduce the IR loss that a BGA, such as first BGA 763a and second BGA 763b of FIG. 7F would otherwise introduce.

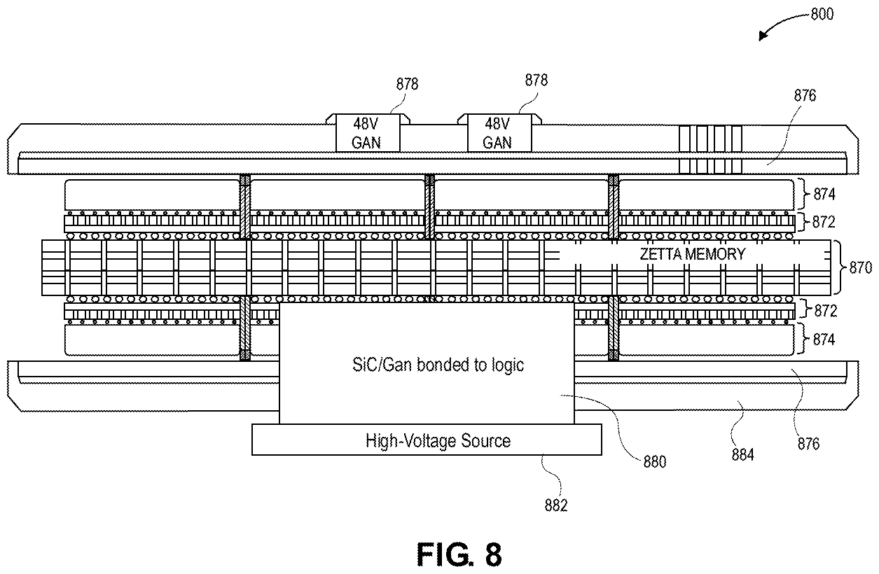

FIG. 8 illustrates a side view of a diagram of a WSE that includes Zetta memory that is powered by high voltage input that is converted using devices within a SiC layer coupled with devices within a GaN layer, in accordance with various embodiments.

Embodiments described herein may be used to enable Zetta scale computing. Zetta scale computing may include an extremely large number of computing devices within a package. For example, the computing devices together may provide on the order of 10²¹ floating-point operations per second (FLOPS). In addition, Zetta scale computing may also involve digital storage in the form of memory, for example DRAM memory, on the order of a zettabyte, or 10²¹ bytes within the package. The large number of computing devices and memory devices within a package may be implemented as a WSE, which may involve an entire wafer or large portions of a wafer, or multiple wafers coupled with each other, that include repeating patterns of compute circuitry on the wafers. This may be done rather than fabricating independent dies that are subsequently stitched together.

One characteristic of a WSE is that it may include components that are tens of millimeters apart. Electrically coupling such components may involve a significant IR drop. In order to mitigate this IR drop, high voltages, for example on the order of 1 kV, may be used to route power from one area of the wafer to another, which may then be converted to 1-1.8V using techniques described herein. In addition, a high-voltage supply may be used to provide significantly more power to a package. For example, a die on a wafer may consume on the order of 100 W, thus, if there are 200 dies on a full wafer, that will require 20 kW to power the entire wafer. If the wafer is part of a WSE that may include multiple wafers bonded with each other, this power consumption will increase with each added wafer.

WSE 800 is an embodiment that includes a plurality of layers that may include a Zetta memory 870, which may include one or more wafers that may be coupled together, where each wafer includes a plurality of memory cells.

In embodiments, interconnect layers 872 may be on the top and the bottom of the Zetta memory 870, and input/output (I/O) layers 874 may be coupled, respectively, with the interconnect layers 872. In embodiments, the I/O layers 874 may include photonics circuitry (not shown). In embodiments, a heat sink 876 may be thermally coupled with the I/O layers 874 and/or the Zetta memory 870. In embodiments, a casing 884 may at least partially surround the Zetta memory 870, the interconnect layers 872, the I/O layers 874, and/or the heat sink 876.

In embodiments, power supplies 878, which may be electrically coupled with voltage source of less than 1 kV, may include devices within a GaN layer, which may be used to step the high voltage source down to 1-1.8 V for use by the Zetta memory 870 as discussed above with respect to FIGS. 1A-1B. In embodiments, a converter 880, which may include transistors within a GaN layer and transistors within a SiC layer that are coupled with each other to step down a voltage that may be greater than 1 kV from a high voltage source 882, down to 1-1.8 V, as discussed above with respect to FIGS. 1A-1B, for use by the Zetta memory 870. In embodiments, the GaN layer may be similar to GaN layer 112 of FIGS. 1A-1B, and the SiC layer may be similar to SiC layer 132 of FIGS. 1A-1B.

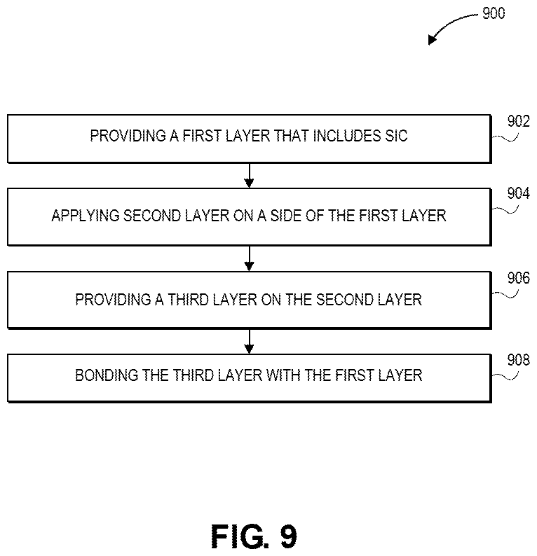

FIG. 9 illustrates an example process for creating a package that includes a SiC layer that is coupled with another layer that includes another material, in accordance with various embodiments. In embodiments, the process 900 may be performed using the techniques, processes, apparatus, and/or systems described herein, and in particular with respect to FIGS. 1A-7G.

At block 902, the process may include providing a first layer that includes SiC. In embodiments, the first layer may be similar to SiC layer 332 of FIG. 3A, or may be similar to SiC layer 432 of FIG. 4B.

At block 904, the process may further include applying second layer on a side of the first layer. In embodiments, the second layer may be similar to the bonding layer 352 of FIG. 3A, or may be similar to the bonding layer 452 of FIG. 4B.

At block 906, the process may further include providing a third layer on the second layer. In embodiments, the third layer may be similar to the A layer 335 of FIG. 3A, or may be similar to the A layer 435 of FIG. 4B.

At block 908, the process may further include bonding the third layer with the first layer. In embodiments, bonding the third layer with the first layer may be similar to an annealing process as described above with respect to FIG. 3B or FIG. 4C.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

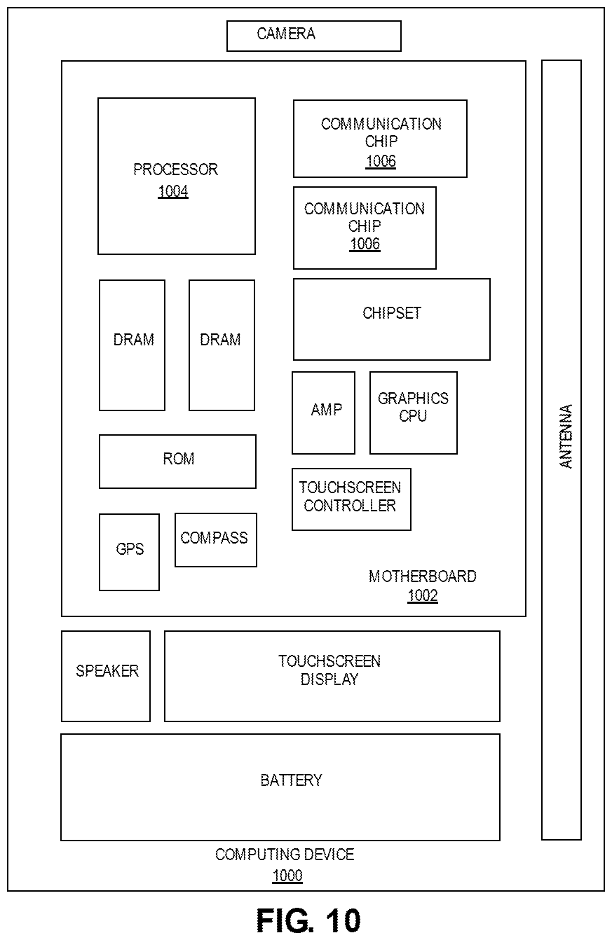

FIG. 10 illustrates a computing device 1000 in accordance with one implementation of the invention. The computing device 1000 houses a board 1002. The board 1002 may include a number of components, including but not limited to a processor 1004 and at least one communication chip 1006. The processor 1004 is physically and electrically coupled to the board 1002. In some implementations the at least one communication chip 1006 is also physically and electrically coupled to the board 1002. In further implementations, the communication chip 1006 is part of the processor 1004.

Depending on its applications, computing device 1000 may include other components that may or may not be physically and electrically coupled to the board 1002. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing device 1000 includes an integrated circuit die packaged within the processor 1004. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of the invention, the integrated circuit die of the communication chip includes one or more devices, such as MOS-FET transistors built in accordance with implementations of the invention.

In further implementations, another component housed within the computing device 1000 may contain an integrated circuit die that includes one or more devices, such as MOS-FET transistors built in accordance with implementations of the invention.

In various implementations, the computing device 1000 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1000 may be any other electronic device that processes data.

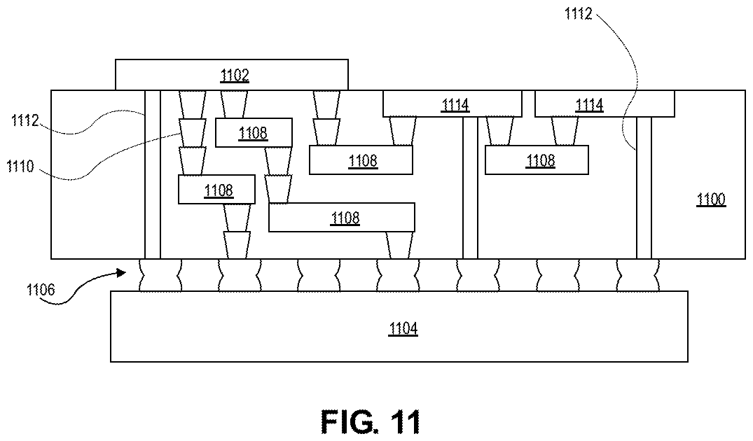

FIG. 11 illustrates an interposer 1100 that includes one or more embodiments of the invention. The interposer 1100 is an intervening substrate used to bridge a first substrate 1102 to a second substrate 1104. The first substrate 1102 may be, for instance, an integrated circuit die. The second substrate 1104 may be, for instance, a memory module, a computer motherboard, or another integrated circuit die. Generally, the purpose of an interposer 1100 is to spread a connection to a wider pitch or to reroute a connection to a different connection. For example, an interposer 1100 may couple an integrated circuit die to a ball grid array (BGA) 1106 that can subsequently be coupled to the second substrate 1104. In some embodiments, the first and second substrates 1102/1104 are attached to opposing sides of the interposer 1100. In other embodiments, the first and second substrates 1102/1104 are attached to the same side of the interposer 1100. And in further embodiments, three or more substrates are interconnected by way of the interposer 1100.

The interposer 1100 may be formed of an epoxy resin, a fiberglass-reinforced epoxy resin, a ceramic material, or a polymer material such as polyimide. In further implementations, the interposer 1100 may be formed of alternate rigid or flexible materials that may include the same materials described above for use in a semiconductor substrate, such as silicon, germanium, and other group III-V and group IV materials.

The interposer 1100 may include metal interconnects 1108 and vias 1110, including but not limited to through-silicon vias (TSVs) 1112. The interposer 1100 may further include embedded devices 1114, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1100. In accordance with embodiments of the invention, apparatuses or processes disclosed herein may be used in the fabrication of interposer 1100.

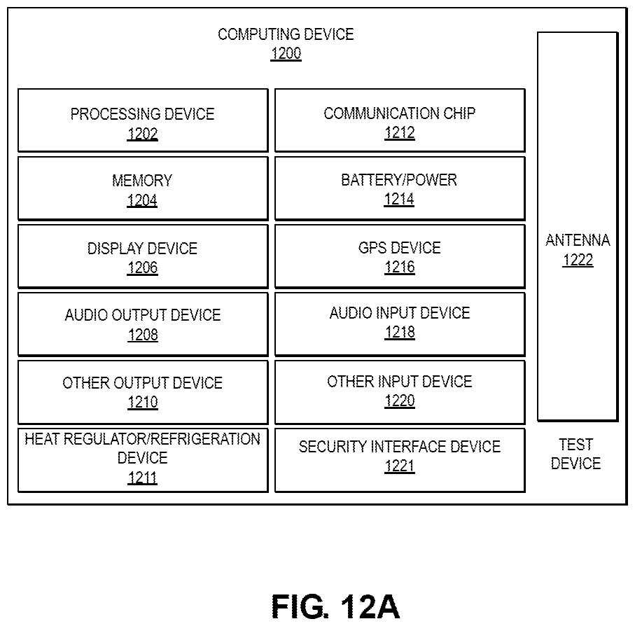

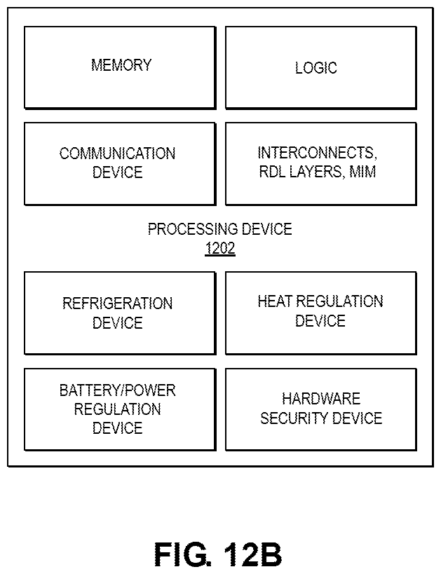

It is to be appreciated that structures described herein may be operated at a low temperature, e.g., in a range of −77 degrees Celsius to 0 degrees Celsius. In one embodiment, a heat regulator/refrigeration device is coupled to a common board having a device with structures such as those described herein coupled thereto, such as described below in association with FIG. 12A. In one embodiment, a heat regulator device and/or refrigeration device is included on a processing device having structures such as those described herein, such as described below in association with FIG. 12B.

FIG. 12A illustrates a computing device 1200 in accordance with one implementation of an embodiment of the present disclosure. The computing device 1200 houses a board. The board may include a number of components, including but not limited to a processing device 1202. The computing device 1200 can also include communication chip 1212. In one embodiment, the processing device 1202 is physically and electrically coupled to the board. In some implementations the communication chip 1212 is also physically and electrically coupled to the board. In further implementations, the communication chip 1212 is part of the processing device 1202.

Depending on its applications, computing device 1200 may include other components that may or may not be physically and electrically coupled to the board. These other components can include, but are not limited to, memory 1204, such as volatile memory (e.g., DRAM), non-volatile memory (e.g., ROM), or flash memory, an antenna 1222, a display device 1206, a battery/power 1214, an audio output device 1208, an audio input device 1218, a global positioning system (GPS) device 1216, an other output device 1210 (such as video output), and other input device 1220 (such as video input), a security interface device 1221, and/or a test device. In one embodiment, a heat regulation/refrigeration device 1211 is included and is coupled to the board, e.g., a device including actively cooled copper channels.

The communication chip 1212 enables wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1212 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1200 may include a plurality of communication chips 1212. For instance, a first communication chip 1212 may be dedicated to shorter range wireless communications such as Wi-Fi and Bluetooth and a second communication chip 1212 may be dedicated to longer range wireless communications such as GPS, EDGE, GPRS, CDMA, WiMAX, LTE, Ev-DO, and others.

The processing device 1202 of the computing device 1200 can include an integrated circuit die in a package. The processing device 1202 may include one or more structures, such as gate-all-around integrated circuit structures having ultra-high conductivity global routing, built in accordance with implementations of embodiments of the present disclosure. The term “processing device” may refer to any device or portion of a device that processes electronic data from registers and/or memory to transform that electronic data into other electronic data that may be stored in registers and/or memory.

FIG. 12B illustrates a processing device in accordance with one implementation of an embodiment of the present disclosure. Referring to FIG. 12B, an exemplary processing device 1202 includes a memory region, a logic region, a communication device region, an interconnects and redistribution layer (RDL) and metal-insulator-metal (MIM) region, a refrigeration device region, a heat regulation device region, a batter/power regulation device region and a hardware security device region. In one embodiment, the refrigeration device region and/or the heat regulation device region is a region including actively cooled copper channels.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The following paragraphs describe examples of various embodiments.

### Examples

Example 1 is an integrated circuit structure comprising: a first layer that includes silicon (Si) and carbon (C); a second layer directly physically coupled with a side of the first layer; and a third layer, wherein the second layer is directly physically coupled with a side of the third layer, and wherein the second layer is between the first layer and the third layer.
Example 2 includes the integrated circuit structure of example 1, wherein the second layer includes a selected one or more of: silicon (Si), oxygen (O), nitrogen (N), carbon (C), SiN, SiON, or SiOCN.
Example 3 includes the integrated circuit structure of examples 1 or 2, wherein the third layer includes a selected one or more of: silicon (Si), germanium (Ge), nitrogen (N), gallium (Ga), oxygen (O), carbon (C), arsenic (As), silicon germanium (SiGe), gallium nitride (GaN), SiC, gallium arsenide (GaAs), gallium oxide (Ga2O3) or diamond.
Example 4 includes the integrated circuit structure of examples 1, 2, or 3, wherein the first layer that includes SiC has a thickness of less than 50 micrometers.
Example 5 includes the integrated circuit structure of examples, 2, 3, or 4, further comprising: a first copper feature on the side of the first layer; a second copper feature on the side of the third layer; and wherein a surface of the first copper feature on the side of the first layer is directly physically coupled to a surface of the second copper feature on the side of the third layer.
Example 6 includes the integrated circuit structure of example 5, wherein the first copper feature is a plurality of copper features, and wherein the second copper feature is a plurality of copper features.
Example 7 includes the integrated circuit structure of examples 5 or 6, wherein the surface of the first copper feature overlaps the surface of the second copper feature.
Example 8 includes the integrated circuit structure of examples 5, 6, or 7, wherein the first copper feature or the second copper feature is a selected one or more of: a via or a pad.
Example 9 includes the integrated circuit structure of examples 1, 2, 3, 4, 5, 6, 7, or 8, further comprising a via that includes copper, the via extending at least partially through the first layer, through the second layer, and at least partially through the third layer.
Example 10 includes the integrated circuit structure of example 9, wherein the via is at least partially surrounded by a barrier layer, and wherein the barrier layer separates at least a portion of the copper in the via from at least a portion of the first layer, the second layer, and at least a portion of the third layer.
Example 11 includes the integrated circuit structure of example 10, wherein the barrier layer is a copper diffusion barrier.
Example 12 is an integrated circuit structure comprising: a first layer that includes silicon (Si) and carbon (C); a second layer directly physically coupled with a first side of the first layer; a side of a third layer on the second layer, wherein at least a portion of the second layer is between the first layer and the third layer; a fourth layer directly physically coupled with a second side of the first layer opposite the first side of the first layer; and a side of a fifth layer on the fourth layer, wherein at least a portion of the fourth layer is between the fifth layer and the first layer.
Example 13 includes the package of example 12, wherein the second layer and the fourth layer include silicon (Si) and one or more of oxygen (O), nitrogen (N), and carbon (C).
Example 14 includes the package of examples 12 or 13, wherein the third layer includes a selected one or more of: silicon (Si), germanium (Ge), nitrogen (N), gallium (Ga), oxygen (O), carbon (C), arsenic (As), silicon germanium (SiGe), gallium nitride (GaN), SiC, gallium arsenide (GaAs), gallium oxide (Ga2O3) or Diamond.
Example 15 includes the package of examples 12, 13, or 14, wherein the first layer has a thickness that is less than 50 micrometers.
Example 16 is a method comprising: providing a first layer that includes silicon carbide (SiC); applying second layer on a side of the first layer; providing a third layer on the second layer; and bonding the third layer with the first layer.
Example 17 includes the method of example 16 wherein bonding the third layer with the first layer further includes applying heat and/or pressure to the first layer, the second layer, and the third layer.
Example 18 includes the method of examples 16 or 17, wherein the second layer includes a selected one or more of: silicon (Si), oxygen (O), nitrogen (N), carbon (C), SiN, SiON, or SiOCN.
Example 19 includes the method of examples 16, 17, or 18, wherein the third layer includes a selected one or more of: silicon (Si), germanium (Ge), nitrogen (N), gallium (Ga), oxygen (O), carbon (C), arsenic (As), silicon germanium (SiGe), gallium nitride (GaN), SiC, gallium arsenide (GaAs), gallium oxide (Ga2O3) or Diamond.
Example 20 includes the method of example 16, 17, 18, or 19, wherein the first layer has a thickness that is less than 50 micrometers.

What is claimed is:

1. An integrated circuit structure comprising:
a first layer that includes silicon (Si) and carbon (C);
a second layer directly physically coupled with a side of the first layer; and
a third layer, wherein the second layer is directly physically coupled with a side of the third layer, and wherein the second layer is between the first layer and the third layer.

2. The integrated circuit structure of claim 1, wherein the second layer includes Si and one or more of: oxygen (O), nitrogen (N), and carbon (C).

3. The integrated circuit structure of claim 1, wherein the third layer includes a selected one or more of: silicon (Si), germanium (Ge), nitrogen (N), gallium (Ga), oxygen (O), carbon (C), arsenic (As), silicon germanium (SiGe), gallium nitride (GaN), SiC, gallium arsenide (GaAs), gallium oxide (Ga₂O₃) or diamond.

4. The integrated circuit structure of claim 1, wherein the first layer that includes SiC has a thickness of less than 50 micrometers.

5. The integrated circuit structure of claim 1, further comprising:
a first copper feature on the side of the first layer;
a second copper feature on the side of the third layer; and
wherein a surface of the first copper feature on the side of the first layer is directly physically coupled to a surface of the second copper feature on the side of the third layer.

6. The integrated circuit structure of claim 5, wherein the first copper feature is a plurality of copper features, and wherein the second copper feature is a plurality of copper features.

7. The integrated circuit structure of claim 5, wherein the surface of the first copper feature overlaps the surface of the second copper feature.

8. The integrated circuit structure of claim 5, wherein the first copper feature or the second copper feature is a selected one or more of: a via or a pad.

9. The integrated circuit structure of claim 1, further comprising a via that includes copper, the via extending at least partially through the first layer, through the second layer, and at least partially through the third layer.

10. The integrated circuit structure of claim 9, wherein the via is at least partially surrounded by a barrier layer, and wherein the barrier layer separates at least a portion of the copper in the via from at least a portion of the first layer, the second layer, and at least a portion of the third layer.

11. The integrated circuit structure of claim 10, wherein the barrier layer is a copper diffusion barrier.

12. An integrated circuit structure comprising:
a first layer that includes silicon (Si) and carbon (C);
a second layer directly physically coupled with a first side of the first layer;
a side of a third layer on the second layer, wherein at least a portion of the second layer is between the first layer and the third layer;
a fourth layer directly physically coupled with a second side of the first layer opposite the first side of the first layer; and
a side of a fifth layer on the fourth layer, wherein at least a portion of the fourth layer is between the fifth layer and the first layer.

13. The integrated circuit structure of claim 12, wherein the second layer and the fourth layer include silicon (Si) and one or more of: oxygen (O), nitrogen (N), and carbon (C).

14. The integrated circuit structure of claim 12, wherein the third layer includes a selected one or more of: silicon (Si), germanium (Ge), nitrogen (N), gallium (Ga), oxygen (O), carbon (C), arsenic (As), silicon germanium (SiGe), gallium nitride (GaN), SiC, gallium arsenide (GaAs), gallium oxide (Ga₂O₃) or Diamond.

15. The integrated circuit structure of claim 12, wherein the first layer has a thickness that is less than 50 micrometers.

16. A method comprising:
providing a first layer that includes silicon carbide (SiC);
applying second layer on a side of the first layer;
providing a third layer on the second layer; and
bonding the third layer with the first layer.

17. The method of claim 16, wherein bonding the third layer with the first layer further includes applying heat and/or pressure to the first layer, the second layer, and the third layer.

18. The method of claim 16, wherein the second layer includes a selected one or more of: silicon (Si), oxygen (O), nitrogen (N), carbon (C), SiN, SiON, or SiOCN.

19. The method of claim 16, wherein the third layer includes a selected one or more of: silicon (Si), germanium (Ge), nitrogen (N), gallium (Ga), oxygen (O), carbon (C), arsenic (As), silicon germanium (SiGe), gallium nitride (GaN), SiC, gallium arsenide (GaAs), gallium oxide (Ga₂O₃) or Diamond.

20. The method of claim 16, wherein the first layer has a thickness that is less than 50 micrometers.
